(19) United States
(12) Patent Application Publication
(10) Pub. No.: US 2023/0155005 A1
(43) Pub. Date: May 18, 2023

(54) SEMICONDUCTOR DEVICE AND METHOD

(71) Applicant: Taiwan Semiconductor Manufacturing Co., Ltd., Hsinchu (TW)

(72) Inventors: Yu-Lien Huang, Jhubei (TW); Hao-Heng Liu, Hsinchu (TW); Po-Chin Chang, Taichung (TW); Yi-Shan Chen, Tainan (TW); Ming-Huan Tsai, Zhubei (TW)

(21) Appl. No.: 17/663,278

(22) Filed: May 13, 2022

Related U.S. Application Data
(60) Provisional application No. 63/278,587, filed on Nov. 12, 2021.

(51) Int. Cl. H01L 29/66; H01L 21/8234; H01L 29/78; H01L 29/417; H01L 27/088

(52) U.S. Cl. CPC H01L 29/66795; H01L 21/823431; H01L 29/7851; H01L 21/823481; H01L 21/823418; H01L 29/41791; H01L 27/0886

(57) ABSTRACT

A method includes forming a first fin and a second fin protruding from a substrate; forming an isolation layer surrounding the first fin and the second fin; epitaxially growing a first epitaxial region on the first fin and a second epitaxial region on the second fin, wherein the first epitaxial region and the second epitaxial region are merged together; performing an etching process on the first epitaxial region and the second epitaxial region, wherein the etching process separates the first epitaxial region from the second epitaxial region; depositing a dielectric material between the first epitaxial region and the second epitaxial region; and forming a first gate stack extending over the first fin.

### PRIORITY CLAIM AND CROSS-REFERENCE

This application claims the benefit of U.S. Provisional Application No. 63/278,587, filed on Nov. 12, 2021, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view, in accordance with some embodiments.

FIGS. 2, 3, 4, 5, 6, 7, 8A, 8B, 9A, 9B, 10A, 10B, and 10C are cross-sectional views of intermediate stages in the manufacturing of FinFETs, in accordance with some embodiments.

FIGS. 11A, 11B, and 11C are cross-sectional views of epitaxial source/drain regions, in accordance with other embodiments.

FIGS. 12A, 12B, 12C, 13A, 13B, and 13C are cross-sectional views of intermediate stages in the manufacturing of FinFETs, in accordance with some embodiments.

FIGS. 14, 15, 16, 17, 18A, 18B, and 18C are cross-sectional views of intermediate stages in the manufacturing of isolation regions, in accordance with some embodiments.

FIGS. 19A, 19B, 19C, 19D, 19E, 19F, 19G, and 19H are cross-sectional views of isolation regions, in accordance with other embodiments.

FIGS. 20A, 20B, 21A, 21B, 21C, 22A, 22B, 22C, 23A, 23B, and 23C are cross-sectional views of intermediate stages in the manufacturing of FinFETs, in accordance with some embodiments.

FIG. 24 is a cross-sectional view of an isolation region, in accordance with other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An isolation region formed between adjacent epitaxial source/drain regions and the methods of forming the same are provided, in accordance with some embodiments. Intermediate stages of forming FinFET devices are illustrated in accordance with some embodiments. Some variations of some embodiments are discussed. In some embodiments, epitaxial source/drain regions of adjacent devices are grown such that the epitaxial source/drain regions are merged together. In accordance with some embodiments, an isolation region is formed between the merged epitaxial source/drain regions of adjacent devices. The isolation region isolates and separates the previously-merged epitaxial source/drain region of one device from the previously-merged epitaxial source/drain region of an adjacent device. In some cases, the use of isolation regions as described herein can increase device density or improve device performance.

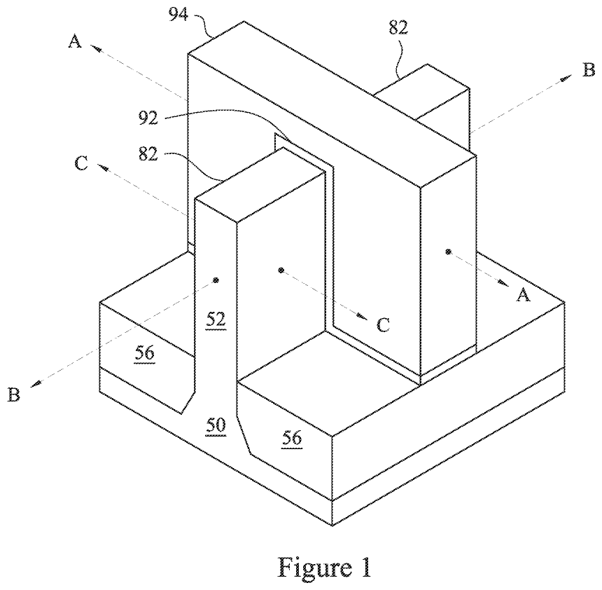

FIG. 1 illustrates an example of a FinFET in a three-dimensional view, in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and gate electrode 94. FIG. 1 further illustrates reference cross-sections that are used in later figures. Cross-section A-A is along a longitudinal axis of the gate electrode 94 and in a direction, for example, perpendicular to the direction of current flow between the source/drain regions 82 of the FinFET. Cross-section B-B is perpendicular to cross-section A-A and is along a longitudinal axis of the fin 52 and in a direction of, for example, a current flow between the source/drain regions 82 of the FinFET. Cross-section C-C is parallel to cross-section A-A and extends through a source/drain region of the FinFET. Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs, nanostructure (e.g., nanosheet, nanowire, gate-all-around, or the like) field effect transistors (NSFETs), or the like.

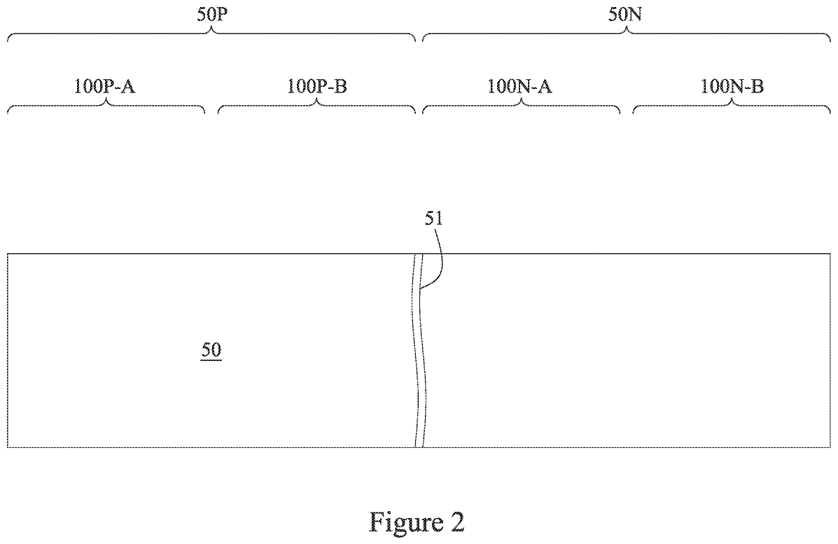

FIGS. 2 through 7 are cross-sectional views of intermediate steps in the manufacturing of FinFET devices, in accordance with some embodiments. FIGS. 2 through 7 illustrate reference cross-section A-A illustrated in FIG. 1, except for multiple fins/FinFETs.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; the like; or combinations thereof.

The substrate 50 has an n-type region 50N and a p-type region 50P. The n-type region 50N can be for forming n-type devices, such as NMOS transistors, e.g., n-type FinFETs. The n-type region 50N is shown having an n-type device region 100N-A within which one n-type device is subsequently formed and an adjacent n-type device region 100N-B within which another n-type device is subsequently formed. A different number of n-type device regions 100N may be formed in an n-type region 50N than shown, and an n-type device region 100N may be adjacent to or physically separated from another n-type device region 100N. The p-type region 50P can be for forming p-type devices, such as PMOS transistors, e.g., p-type FinFETs. The p-type region 50P is shown having a p-type device region 100P-A within which one p-type device is subsequently formed and an adjacent p-type device region 100P-B within which another p-type device is subsequently formed. A different number of p-type device regions 100P may be formed in a p-type region 50P than shown, and a p-type device region 100P may be adjacent to or physically separated from another p-type device region 100P. The n-type region 50N may be physically separated from the p-type region 50P (as illustrated by divider 51), and any number of device features (e.g., device regions, other active devices, doped regions, isolation structures, etc.) may be disposed between the n-type region 50N and the p-type region 50P. In other embodiments, an n-type device region 100N may be adjacent to a p-type device region 100P.

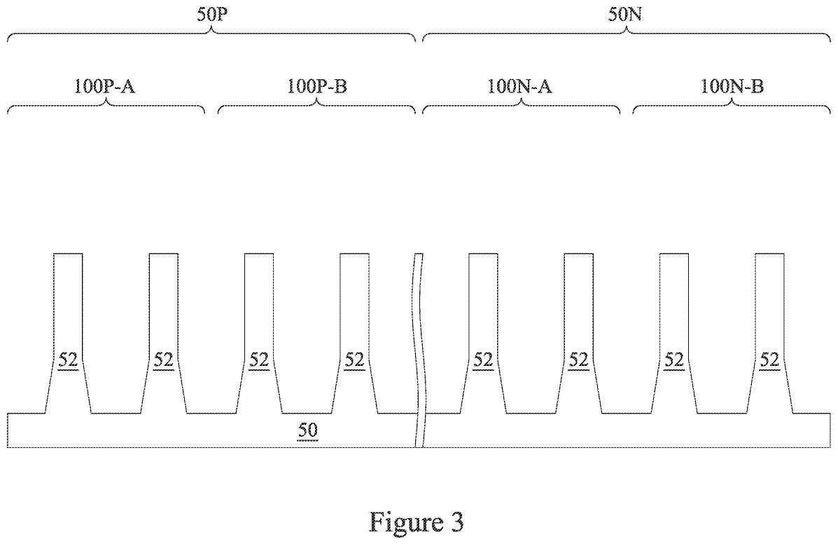

In FIG. 3, fins 52 are formed in the substrate 50, in accordance with some embodiments. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

The fins may be patterned by any suitable method. For example, the fins 52 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. In some embodiments, the mask (or other layer) may remain on the fins 52.

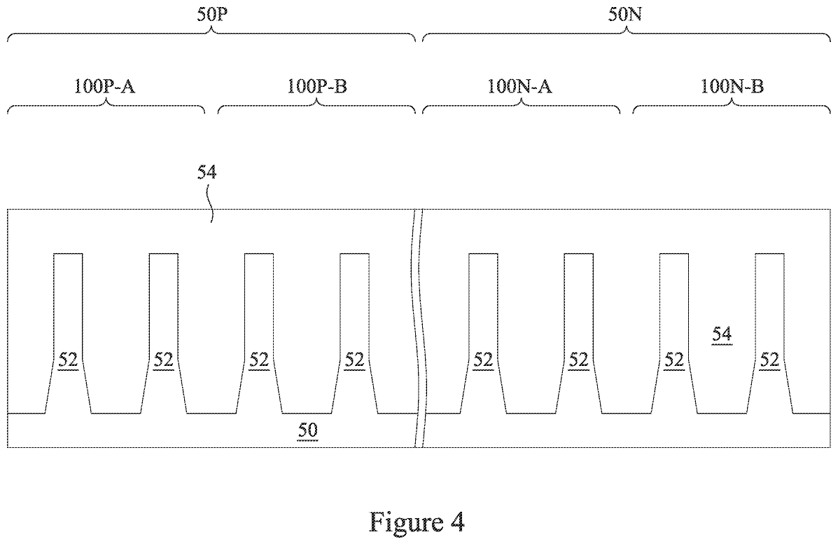

In FIG. 4, an insulation material 54 is formed over the substrate 50 and between neighboring fins 52. The insulation material 54 may be an oxide, such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments a liner (not shown) may first be formed along a surface of the substrate 50 and the fins 52. Thereafter, a fill material, such as those discussed above, may be formed over the liner.

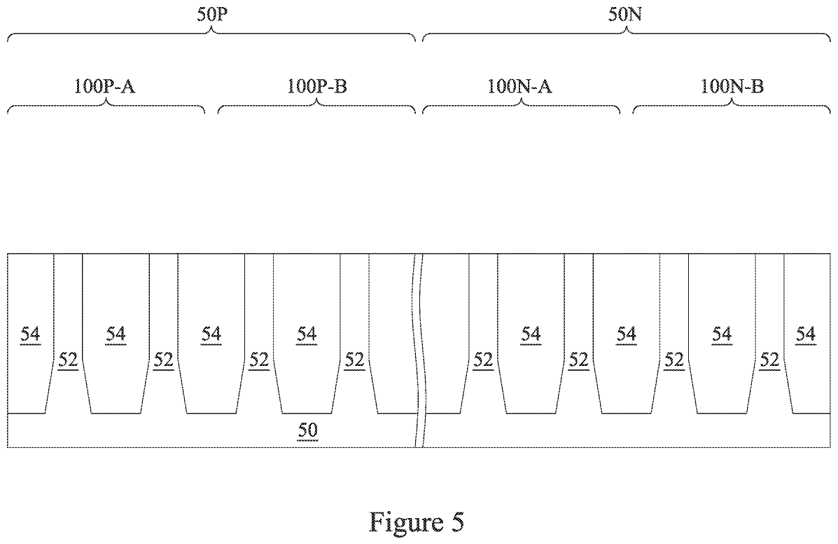

In FIG. 5, a removal process is applied to the insulation material 54 to remove excess insulation material 54 over the fins 52. In some embodiments, a planarization process such as a chemical mechanical polish (CMP), an etch-back process, combinations thereof, or the like may be utilized. The planarization process exposes the fins 52 such that top surfaces of the fins 52 and the insulation material 54 are level after the planarization process is complete. In embodiments in which a mask remains on the fins 52, the planarization process may expose the mask or remove the mask such that top surfaces of the mask or the fins 52, respectively, and the insulation material 54 are level after the planarization process is complete.

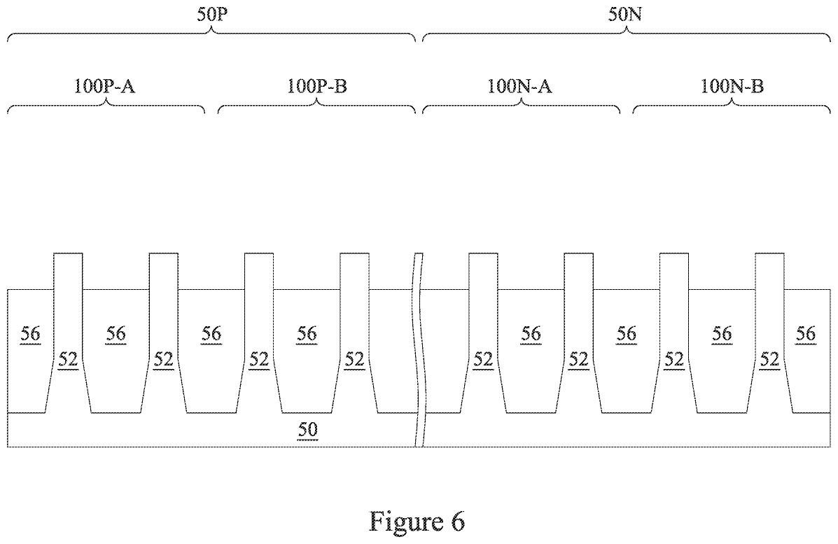

In FIG. 6, the insulation material 54 is recessed to form Shallow Trench Isolation (STI) regions 56. The insulation material 54 is recessed such that upper portions of fins 52 in the n-type region 50N and in the p-type region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, an oxide removal using, for example, dilute hydrofluoric (dHF) acid may be used.

The process described with respect to FIGS. 2 through 6 is just one example of how the fins 52 may be formed. In some embodiments, the fins may be formed by an epitaxial growth process. For example, a dielectric layer can be formed over a top surface of the substrate 50, and trenches can be etched through the dielectric layer to expose the underlying substrate 50. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins 52. For example, the fins 52 in FIG. 5 can be recessed, and a material different from the fins 52 may be epitaxially grown over the recessed fins 52. In such embodiments, the fins 52 comprise the recessed material as well as the epitaxially grown material disposed over the recessed material. In an even further embodiment, a dielectric layer can be formed over a top surface of the substrate 50, and trenches can be etched through the dielectric layer. Heteroepitaxial structures can then be epitaxially grown in the trenches using a material different from the substrate 50, and the dielectric layer can be recessed such that the heteroepitaxial structures protrude from the dielectric layer to form the fins 52. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in n-type region 50N (e.g., an NMOS region) different from the material in p-type region 50P (e.g., a PMOS region). In various embodiments, upper portions of the fins 52 may be formed from silicon germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming a III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further in FIG. 6, appropriate wells (not shown) may be formed in the fins 52 and/or the substrate 50. In some embodiments, a P well may be formed in the n-type region 50N, and an N well may be formed in the p-type region 50P. In some embodiments, a P well or an N well are formed in both the n-type region 50N and the p-type region 50P.

In the embodiments with different well types, the different implant steps for the n-type region 50N and the p-type region 50P may be achieved using a photoresist and/or other masks (not shown). For example, a photoresist may be formed over the fins 52 and the STI regions 56 in the n-type region 50N. The photoresist is patterned to expose the p-type region 50P of the substrate 50. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, the like, or a combination thereof implanted in the region to a concentration of equal to or less than about 10¹⁸ cm⁻³, such as in the range of about 10¹⁶ cm⁻³ to about 10¹⁸ cm⁻³. After the implant, the photoresist is removed, such as by an acceptable ashing process.

Following the implanting of the p-type region 50P, a photoresist is formed over the fins 52 and the STI regions 56 in the p-type region 50P. The photoresist is patterned to expose the n-type region 50N of the substrate 50. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration of equal to or less than about 10¹⁸ cm⁻³, such as in the range of about 10¹⁶ cm⁻³ to about 10¹⁸ cm⁻³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

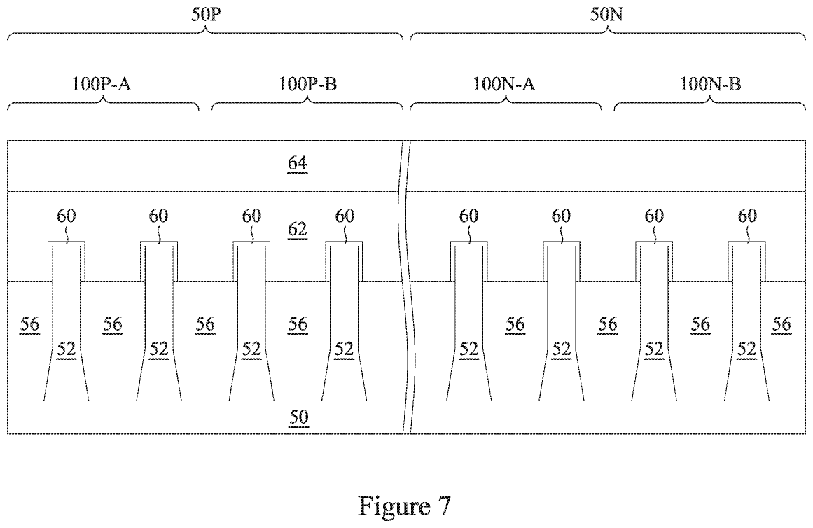

In FIG. 7, a dummy dielectric layer 60 is formed on the fins 52, in accordance with some embodiments. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques for depositing the selected material. The dummy gate layer 62 may be made of other materials that have a high etching selectivity from the etching of isolation regions, e.g., the STI regions 56 and/or the dummy dielectric layer 60. The mask layer 64 may include one or more layers of, for example, silicon nitride, silicon oxynitride, or the like. In this example, a single dummy gate layer 62 and a single mask layer 64 are formed across the n-type region 50N and the p-type region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending over the STI regions and between the dummy gate layer 62 and the STI regions 56.

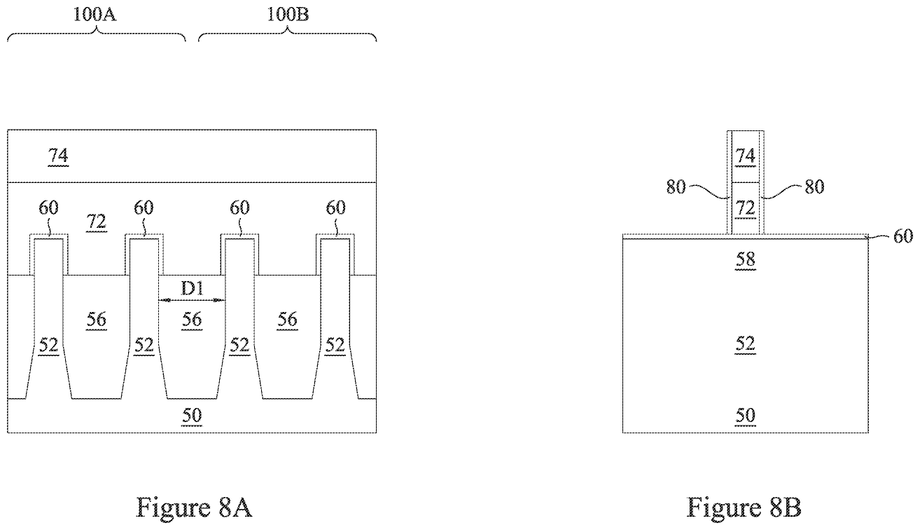

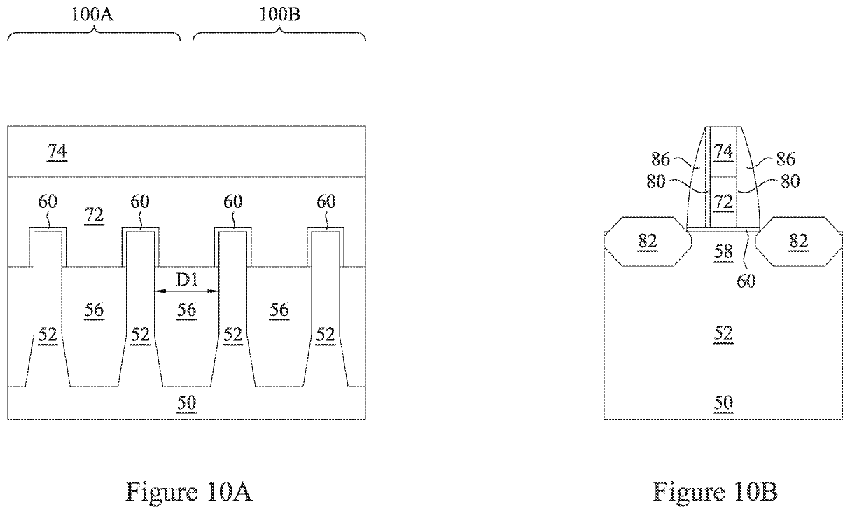

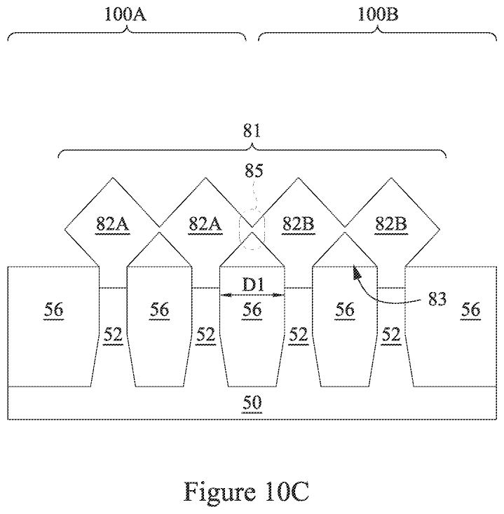

FIGS. 8A through 23C illustrate various additional steps in the manufacturing of embodiment devices. FIGS. 8A, 9A, 10A, 12A, 13A, 18A, 20A, 21A, 22A, and 23A are illustrated along reference cross-section A-A illustrated in FIG. 1, except for multiple fins/FinFETs. For example, FIG. 8A illustrates adjacent device regions 100A and 100B along reference cross-section A-A. In other embodiments, a device region 100A or 100B may have a different number of fins 52 than shown, such as one fin 52 or more than two fins 52. FIGS. 8B, 9B, 10B, 12B, 13B, 18B, 20B, 21B, 21C, 22B and 23B are illustrated along reference cross-section B-B illustrated in FIG. 1, except for multiple fins/FinFETs. For example, FIG. 8B is illustrated along reference cross-section B-B in either device region 100A or device region 100B. FIGS. 10C, 11A, 11B, 11C, 12C, 13C, 14, 15, 16, 17, 18C, 19A, 19B, 19C, 19D, 19E, 19F, 19G, 19H, 22C, and 23C are illustrated along reference cross-section C-C illustrated in FIG. 1, except for multiple fins/FinFETs.

FIGS. 8A through 23C illustrate features in either of the n-type region 50N and the p-type region 50P, unless otherwise described in the text accompanying each figure. For example, the structures illustrated in FIGS. 8A through 23C may be applicable to both the n-type region 50N and the p-type region 50P. Accordingly, the adjacent device regions 100A-B shown in FIGS. 8A through 23C may correspond to n-type device regions 100NA-B or to p-type device regions 100PA-B, unless otherwise described in the text accompanying each figure. Differences (if any) in the structures of the n-type region 50N and the p-type region 50P are described in the text accompanying each figure. In some embodiments, the adjacent fins 52 of the two device regions 100A-B may be separated by a distance D1, which may be in the range of about 26 nm to about 190 nm. In some embodiments, the adjacent fins 52 of the two device regions 100A-B may have a pitch in the range of about 36 nm to about 200 nm. The other fins 52 of the device regions 100A-B may have the same pitch or a different pitch than the adjacent fins 52. Other distances are possible. In some cases, the techniques described herein may allow for the fins 52 of adjacent device regions 100 to have a smaller separation distance D1 (e.g., a smaller pitch), described in greater detail below.

In FIGS. 8A and 8B, the mask layer 64 (see FIG. 7) may be patterned using acceptable photolithography and etching techniques to form masks 74. FIG. 8A illustrates adjacent device regions 100A and 100B along reference cross-section A-A, and FIG. 8B is illustrated along reference cross-section B-B in either device region 100A or device region 100B. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates 72. The dummy gates 72 may also have a lengthwise direction substantially perpendicular to the lengthwise direction of respective epitaxial fins 52.

Further in FIGS. 8A and 8B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, similar to the implants discussed above in FIG. 6, a mask, such as a photoresist, may be formed over the n-type region 50N, while exposing the p-type region 50P, and appropriate type (e.g., p-type) impurities may be implanted into the exposed fins 52 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 52 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in the range of about 10¹⁵ cm⁻³ to about 10¹⁹ cm⁻³. An anneal may be used to repair implant damage and to activate the implanted impurities.

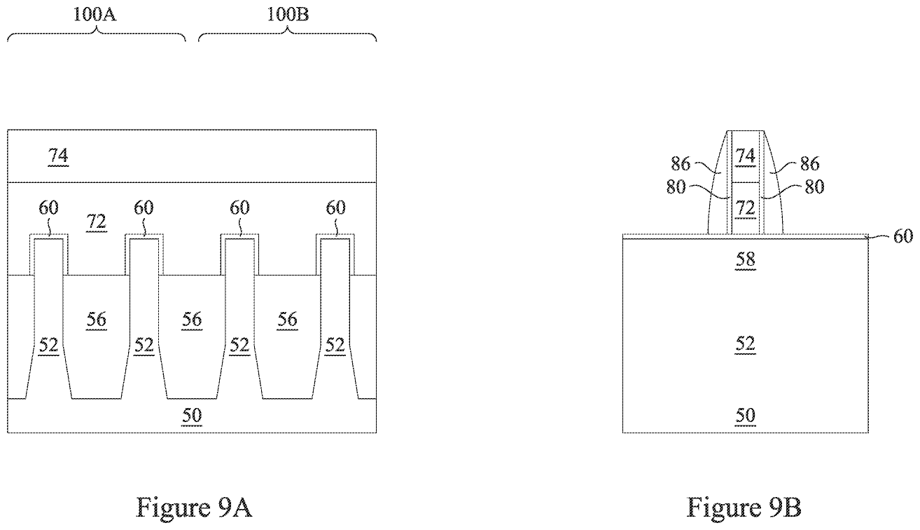

In FIGS. 9A and 9B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may be silicon oxide, silicon nitride, silicon oxynitride, silicon carbonitride, a combination thereof, or the like.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers), spacers may be formed and removed, and/or the like. Furthermore, the n-type and p-type devices may be formed using different structures and steps. For example, LDD regions for n-type devices may be formed prior to forming the gate seal spacers 80 while the LDD regions for p-type devices may be formed after forming the gate seal spacers 80.

In FIGS. 10A, 10B, and 10C, epitaxial regions 82 are formed in the fins 52, in accordance with some embodiments. The epitaxial regions 82 may be, for example, epitaxial source/drain regions. FIG. 10A illustrates adjacent device regions 100A and 100B along reference cross-section A-A. FIG. 10B is illustrated along reference cross-section B-B in either device region 100A or device region 100B. FIG. 10C illustrates adjacent device regions 100A and 100B along reference cross-section C-C. In FIG. 10C, the epitaxial regions 82 formed in the device region 100A are indicated as epitaxial regions 82A, and the epitaxial regions 82 formed in the device region 100B are indicated as epitaxial regions 82B. FIG. 10C shows two epitaxial regions 82A formed in the device region 100A and two epitaxial regions 82B formed in the device region 100B, but more or fewer epitaxial regions 82A or 82B may be formed in other embodiments. As used herein, “epitaxial regions 82” may refer to the epitaxial regions 82A of the device region 100A and/or the epitaxial regions 82B of the device region 100B, in some cases. For example, the epitaxial regions 82 shown in FIG. 10B may correspond to either epitaxial regions 82A or epitaxial regions 82B. In some embodiments, the epitaxial regions 82A and the epitaxial regions 82B are grown simultaneously and have substantially similar compositions (e.g., semiconductor material(s), doping, etc.). As shown in FIG. 10C, the epitaxial regions 82A and the epitaxial regions 82B may be merged together into a merged epitaxial structure 81, described in greater detail below.

The epitaxial regions 82 are formed in the fins 52 such that each dummy gate 72 is disposed between respective neighboring pairs of the epitaxial regions 82. In some embodiments, the epitaxial regions 82 may extend into the fins 52 and may also penetrate through the fins 52. In some embodiments, the gate spacers 86 are used to separate the epitaxial regions 82 from the dummy gates 72 by an appropriate lateral distance so that the epitaxial regions 82 do not short out subsequently formed gates of the resulting FinFETs. In some embodiments, the spacer etch used to form the gate spacers 86 may be adjusted to remove the spacer material to allow the epitaxially grown region to extend to the surface of the STI region 56, as shown in FIG. 10C. A material of the epitaxial regions 82 may be selected to exert stress in the respective channel regions 58, thereby improving performance. In some embodiments, the epitaxial regions 82 may be formed of one semiconductor material, multiple layers of different semiconductor materials, multiple layers of different compositions of one or more semiconductor materials, or the like.

The epitaxial regions 82 in the n-type region 50N may be formed by masking the p-type region 50P and etching source/drain regions of the fins 52 in the n-type region 50N to form recesses in the fins 52. Then, the epitaxial regions 82 in the n-type region 50N are epitaxially grown in the recesses. In some embodiments, the epitaxial regions 82A and the epitaxial regions 82B may be grown simultaneously. The epitaxial source/drain regions 82 may include any acceptable material, such as appropriate for n-type FinFETs. For example, if the fin 52 is silicon, the epitaxial regions 82 in the n-type region 50N may include materials exerting a tensile strain in the channel region 58, such as silicon, silicon carbide, phosphorous-doped silicon carbide, silicon phosphide, the like, or a combination thereof. The epitaxial regions 82 in the n-type region 50N may have surfaces raised from respective surfaces of the fins 52 and may have facets.

The epitaxial regions 82 in the p-type region 50P may be formed by masking the n-type region 50N and etching regions of the fins 52 in the p-type region 50P to form recesses in the fins 52. Then, the epitaxial regions 82 in the p-type region 50P are epitaxially grown in the recesses. In some embodiments, the epitaxial regions 82A and the epitaxial regions 82B may be grown simultaneously. The epitaxial regions 82 may include any acceptable material, such as appropriate for p-type FinFETs. For example, if the fin 52 is silicon, the epitaxial regions 82 in the p-type region 50P may comprise materials exerting a compressive strain in the channel region 58, such as silicon germanium, boron-doped silicon germanium, germanium, germanium tin, the like, or a combination thereof. The epitaxial regions 82 in the p-type region 50P may have surfaces raised from respective surfaces of the fins 52 and may have facets.

The epitaxial regions 82 and/or the fins 52 may be implanted with dopants to form source/drain regions, similar to the process previously discussed for forming lightly-doped source/drain regions, followed by an anneal. The source/drain regions may have an impurity concentration in the range of about 10¹⁹ cm⁻³ to about 10²¹ cm⁻³. The n-type and/or p-type impurities for source/drain regions may be any of the impurities previously discussed. In some embodiments, the epitaxial regions 82 may be in situ doped during growth.

As a result of the epitaxy processes used to form the epitaxial regions 82 in the n-type region 50N and the p-type region 50P, upper surfaces of the epitaxial regions 82 may have facets that expand laterally outward beyond sidewalls of the fins 52. In some embodiments, these facets cause adjacent epitaxial regions 82 to merge, as illustrated by FIG. 10C. For example, in some embodiments, epitaxial regions 82A in the device region 100A may merge together, or epitaxial regions 82B of the device region 100B may merge together, as shown in FIG. 10C. In some embodiments, an epitaxial region 82A of the device region 100A may merge with an adjacent epitaxial region 82B of the device region 100B and form a merged epitaxial structure 81, as shown in FIG. 10C. A merged epitaxial structure 81 may be, for example, a physically and electrically continuous structure comprising two or more epitaxial regions 82 that are merged together. The region of the merged epitaxial structure 81 where the epitaxial region 82A and the adjacent epitaxial region 82B merge together during epitaxial growth is indicated in FIG. 10C as merging region 85. A merged epitaxial structure 81 may comprise two or more merged epitaxial regions 82 formed in two or more device regions 100. For example, the merged epitaxial structure 81 in FIG. 10C is shown as formed of four merged epitaxial regions 82 (e.g., two epitaxial regions 82A and two epitaxial regions 82B). In other embodiments, a merged epitaxial structure 81 may comprise more or fewer merged epitaxial regions 82 than shown, or may comprise merged epitaxial regions 82 formed in more than two device regions 100.

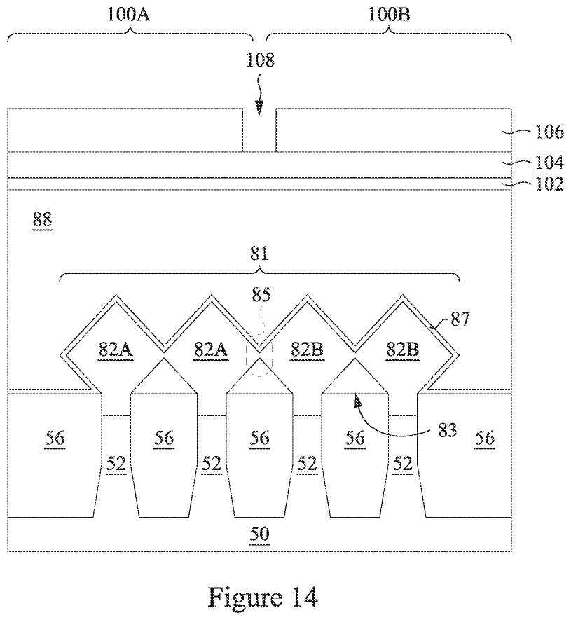

In some cases, an epitaxial region 82A may merge with an epitaxial region 82B when the epitaxial regions 82A and 82B are grown a lateral distance that is greater than half of the separation distance D1 between the corresponding adjacent fins 52. In this manner, the epitaxial regions 82A and 82B may form a merged epitaxial structure 81 by forming adjacent fins 52 having an appropriately small distance D1 and/or by growing the epitaxial regions 82A and 82B to have an appropriately large size, in some embodiments. As described below for FIGS. 14-18C, epitaxial regions 82A and epitaxial regions 82B that are merged together into a merged epitaxial structure 81 may be subsequently isolated by forming an isolation region 110 between the epitaxial regions 82A and the epitaxial regions 82B, in some embodiments. In some cases, air gaps 83 may be formed under merged epitaxial regions 82, such as under the merging region 85 or the like. In other cases, no air gap 83 is present.

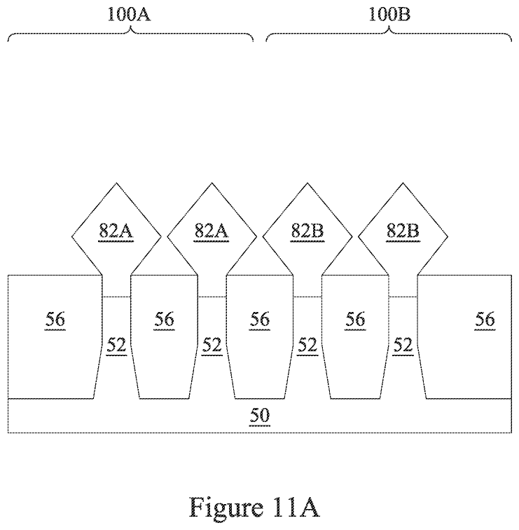

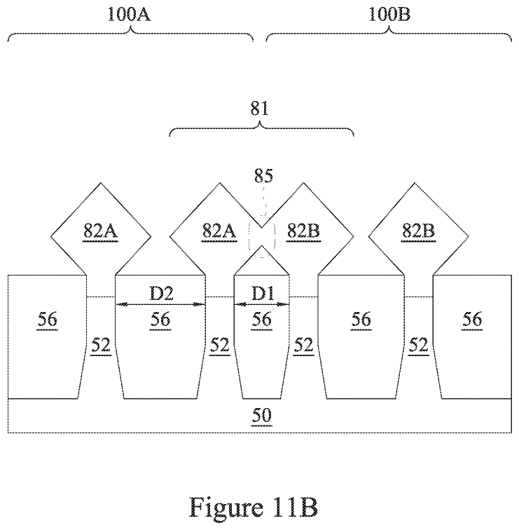

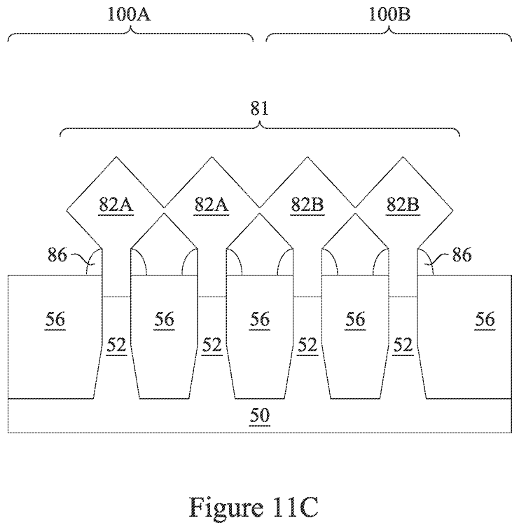

FIGS. 11A, 11B, and 11C illustrate epitaxial regions 82 in accordance with other embodiments. The epitaxial regions 82 may be similar to the epitaxial regions 82 described for FIGS. 10A-10C, and may be formed using similar techniques. FIG. 11A shows an embodiment in which the source/drain regions 82 remain separated (e.g., unmerged) after the epitaxy process is completed. In other embodiments, some epitaxial regions 82 may be merged and some epitaxial regions 82 may be separated. For example, as shown in FIG. 11B, the epitaxial regions 82A of the device region 100A may be separated from each other and the epitaxial regions 82B may be separated from each other, but an epitaxial region 82A may be merged with an epitaxial region 82B. In some embodiments, fins 52 with unmerged epitaxial regions 82 may be separated by a distance D2 that is greater than a separation distance D1 of fins 52 with merged epitaxial regions 82. Other combinations or arrangements of merged and unmerged epitaxial regions 82 are possible, and all such variations are considered within the scope of the present disclosure. FIG. 11C illustrates an embodiment in which the spacer material is left remaining such that the gate spacers 86 are formed covering a portion of the sidewalls of the fins 52 that extend above the STI regions 56, thereby blocking the epitaxial growth.

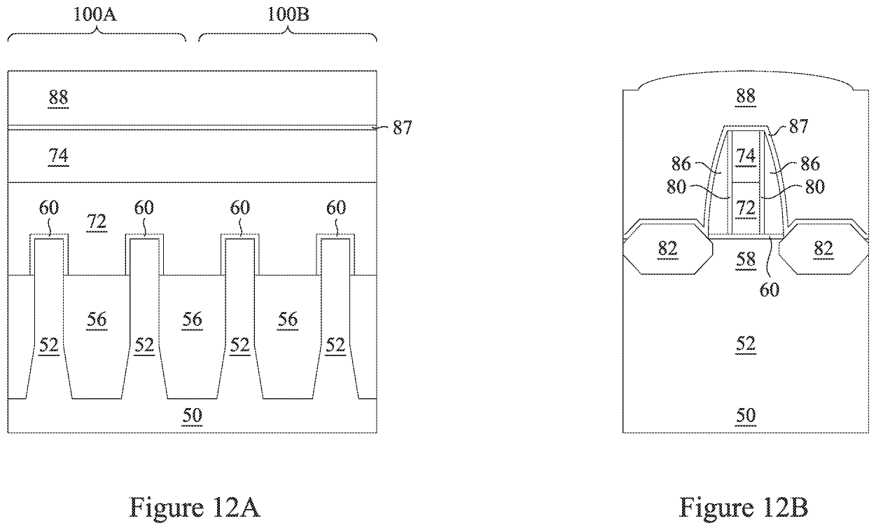

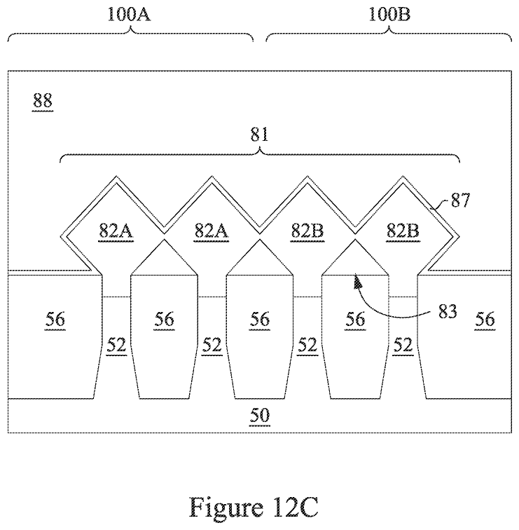

In FIGS. 12A, 12B, and 12C, a first interlayer dielectric (ILD) 88 is deposited over the structure illustrated in FIGS. 10A-10C. The first ILD 88 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), the like, or a combination thereof. Other insulation materials formed by any acceptable process may be used. In some embodiments, a contact etch stop layer (CESL) 87 is disposed between the first ILD 88 and the epitaxial source/drain regions 82, the masks 74, and the gate spacers 86. The CESL 87 may comprise a dielectric material, such as, silicon nitride, silicon oxide, silicon oxynitride, or the like, having a lower etch rate than the material of the overlying first ILD 88.

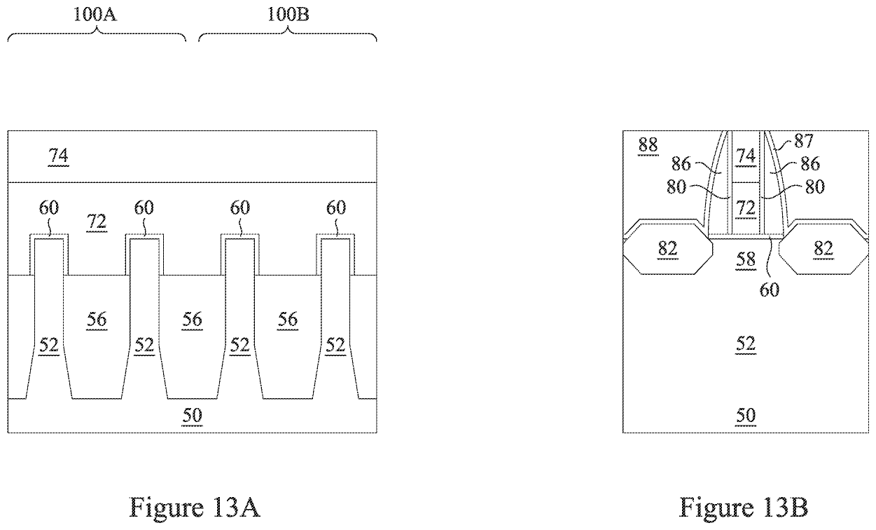

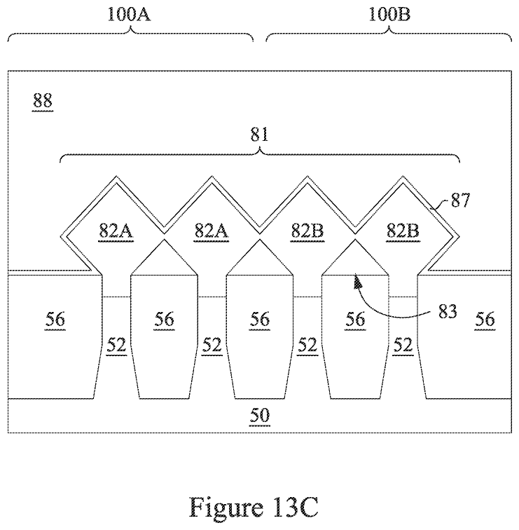

In FIGS. 13A, 13B, and 13C, a planarization process, such as a CMP, may be performed to level the top surface of the first ILD 88 with the top surfaces of the dummy gates 72 or the masks 74. In some embodiments, after the planarization process, top surfaces of the masks 74, the gate seal spacers 80, the gate spacers 86, and/or the first ILD 88 are level. Accordingly, the top surfaces of the masks 74 are exposed through the first ILD 88, as shown in FIGS. 13A-13B. In other embodiments, the planarization process may also remove the masks 74 on the dummy gates 72 and portions of the gate seal spacers 80 and the gate spacers 86 along sidewalls of the masks 74. In these embodiments, after the planarization process, top surfaces of the dummy gates 72, the gate seal spacers 80, the gate spacers 86, and the first ILD 88 are level. Accordingly, the top surfaces of the dummy gates 72 are exposed through the first ILD 88.

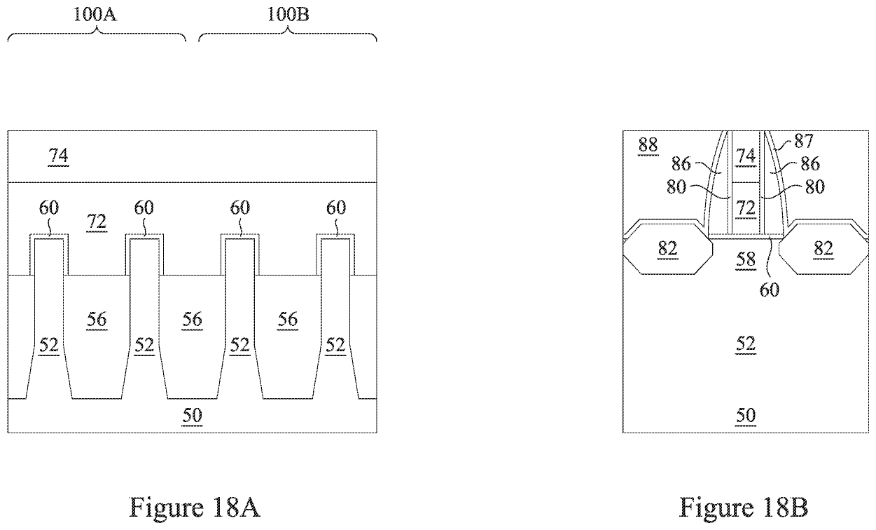

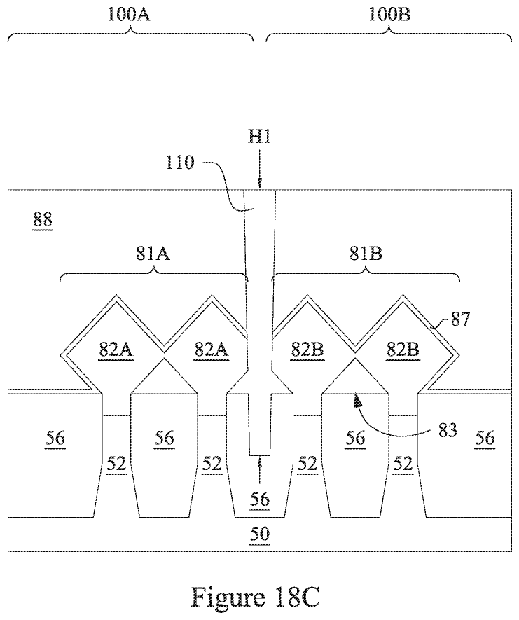

FIGS. 14 through 18 are cross-sectional views of intermediate stages in the formation of an isolation region 110 (see FIG. 18C) between the epitaxial regions 82A and the epitaxial regions 82B of the merged epitaxial structure 81, in accordance with some embodiments. An isolation region 110 may physically and electrically isolate two or more epitaxial regions 82 that were previously part of the same merged epitaxial structure 81, in some embodiments. FIGS. 14 through 18 are illustrated along reference cross-section C-C.

Turning to FIG. 14, a pad layer 102, a hard mask layer 104, and a patterned photoresist 106 are formed over the structure shown in FIG. 13C, in accordance with some embodiments. A Bottom Anti-Reflective Coating (BARC, not shown) may also be formed between the hard mask layer 104 and the patterned photoresist 106. In accordance with some embodiments, the pad layer 102 comprises a metal-containing material such as titanium nitride, tantalum nitride, the like, or a combination thereof. The pad layer 102 may comprise a dielectric material such as silicon oxide or the like, in some embodiments. The hard mask layer 104 may be formed of a material such as silicon nitride, silicon oxynitride, silicon carbonitride, silicon oxycarbonitride, the like, or a combination thereof. The pad layer 102 and the hard mask layer 104 may be formed using suitable techniques, such as ALD, PECVD, or the like. Other materials or deposition techniques are possible.

The photoresist 106 is then deposited over the hard mask layer 104, in some embodiments. The photoresist 106 may be a single layer or a multi-layer structure. The photoresist 106 may be patterned using suitable photolithographic techniques to form an opening 108, in some embodiments. The opening 108 may extend directly over a merging region 85 of the epitaxial regions 82, such as the portion where an epitaxial region 82A and an epitaxial region 82B merge together. The opening 108 may expose the hard mask layer 104, in some embodiments.

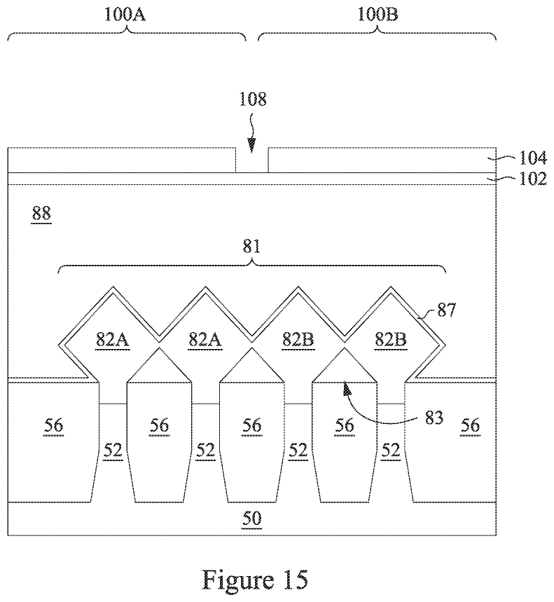

FIG. 15 illustrates the etching of the hard mask layer 104, in which the patterned photoresist 106 (see FIG. 14) is used as an etching mask. The hard mask layer 104 may be etched using, for example, an anisotropic etching process. In this manner, the opening 108 may be extended through the hard mask layer 104 and expose the pad layer 102. In some embodiments, the photoresist 106 may then be removed using a suitable process, such as an ashing process or the like.

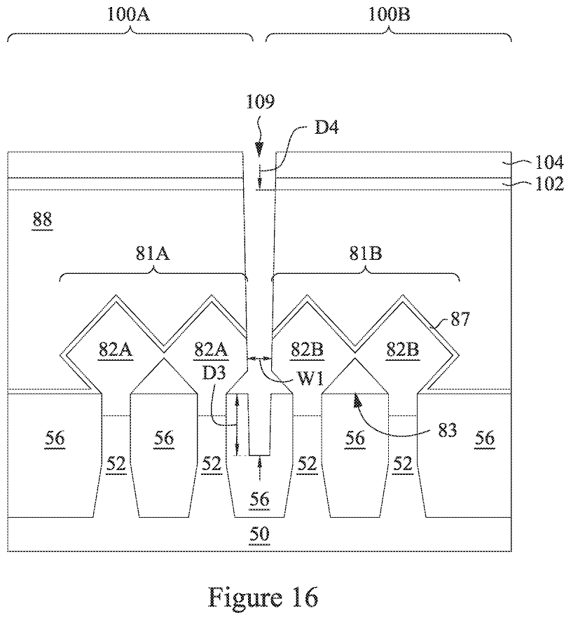

In FIG. 16, an etching process is performed to form a trench 109 that extends through the merged epitaxial structure 81 to separate the epitaxial regions 82A from the epitaxial regions 82B, in accordance with some embodiments. For example, the etching process may remove the merging region 85 (see FIG. 14) between an epitaxial region 82A and an epitaxial region 82B of the merged epitaxial structure 81. After performing the etching process, the merged epitaxial structure 81 is separated (e.g., are “cut”) into two separate and electrically isolated epitaxial structures 81A and 81B. The epitaxial structure 81A is formed of one or more epitaxial regions 82A, and the epitaxial structure 81B is formed of one or more epitaxial regions 82B. In this manner, epitaxial regions 82 formed in adjacent device regions 100 may be physically and electrically isolated. It should be understood that a single merged epitaxial structure 81 may be separated into more than two epitaxial structures by additional simultaneous etching processes.

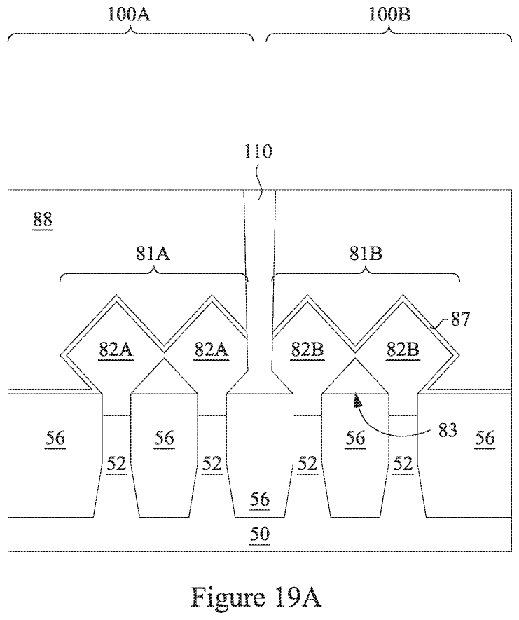

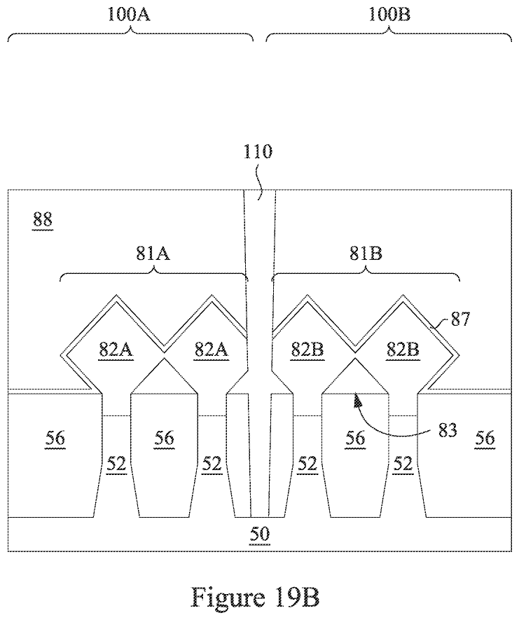

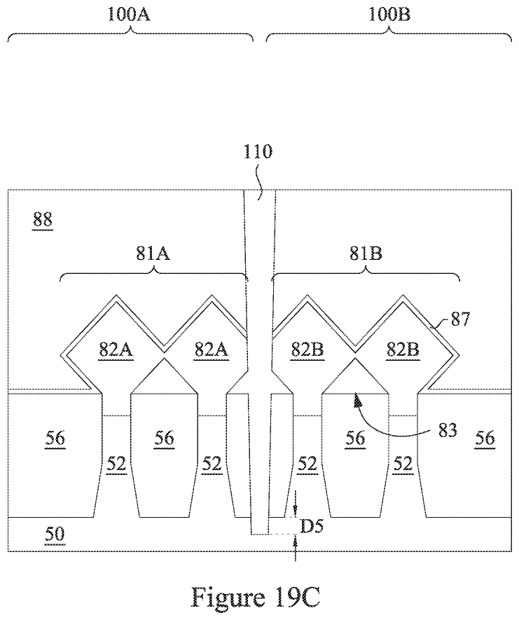

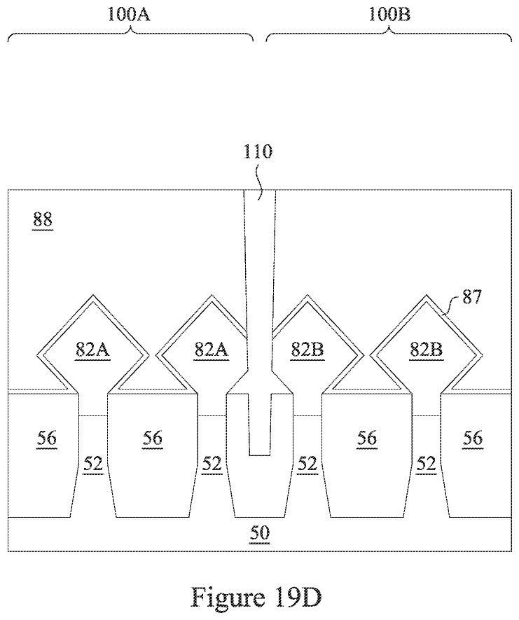

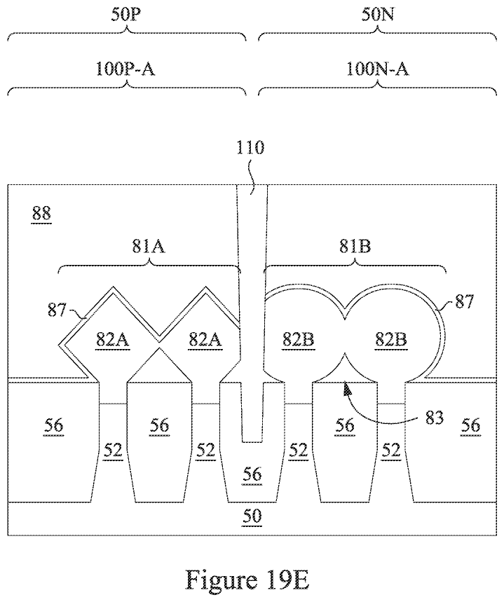

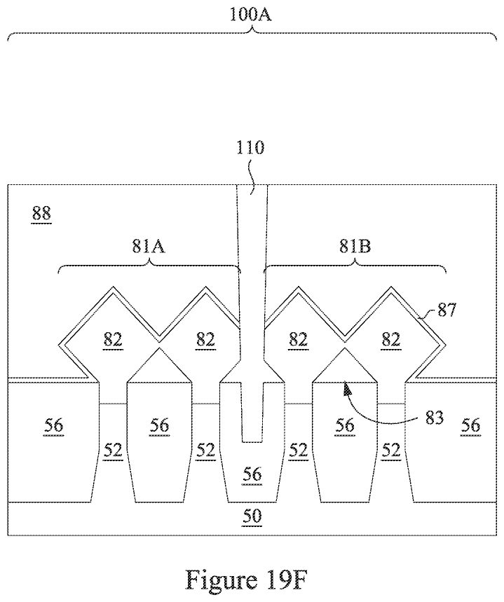

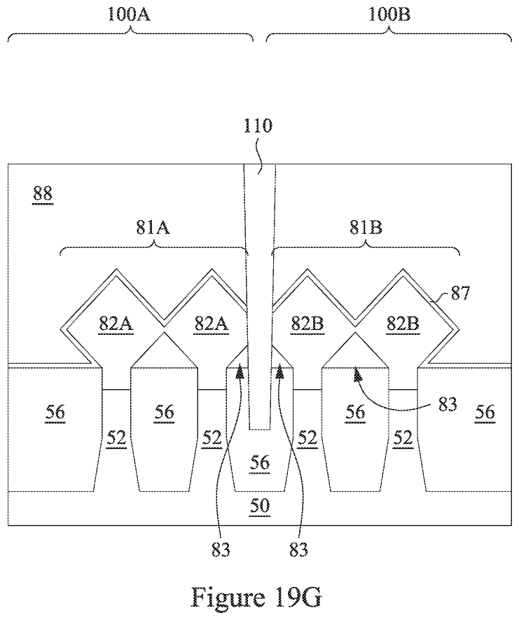

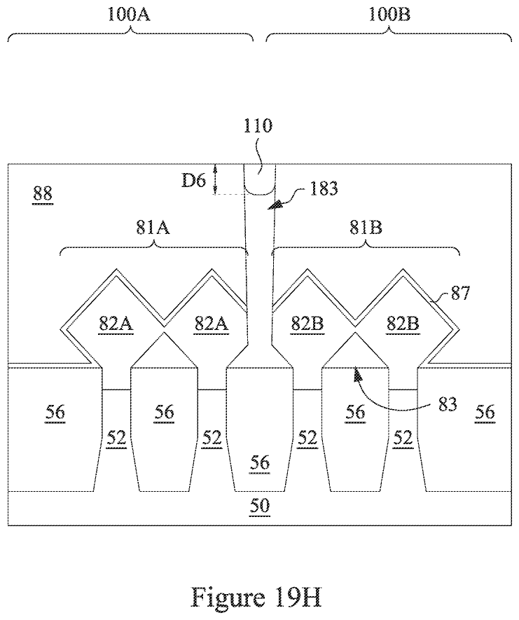

In some embodiments, the etching process forms the trench 109 by extending the opening 108 (see FIG. 15) through the pad layer 102, the first ILD 88, the CESL 87, and the merged epitaxial structure 81. In some embodiments, the trench 109 forms a gap (or “cut”) in the merged epitaxial structure 81 that has a width W1 in the range of about 8 nm to about 30 nm. The width W1 may be between 10% and 80% of the separation distance D1 (see FIG. 10C), in some embodiments. Other widths or percentages are possible. The trench 109 may also expose an air gap 83 (if present) and/or a STI region 56. In some embodiments, the etching process is continued until the trench 109 extends below a top surface of a STI region 56, as shown in FIG. 16. In some embodiments, the trench 109 extends below a top surface of a STI region 56 a distance D3 that is in the range of about 0 nm and about 60 nm. In this manner, the distance D3 may be between 0% and 100% of the thickness of a STI region 56, in some embodiments. The trench 109 may have a depth D4 below a top surface of the first ILD 88 (see FIG. 18C) that is in the range of about 20 nm to about 90 nm. Other distances are possible. In other embodiments, the etching process may not extend the trench 109 into a STI region 56, and the bottom of the trench 109 may thus be defined by a top surface of a STI region 56 (see FIG. 19A). In other embodiments, the etching process is continued until the trench 109 extends through a STI region 56 and exposes the substrate 50. In such embodiments, the etching process may stop on a top surface of the substrate 50 (see FIG. 19B) or may extend below a top surface of the substrate 50 (see FIG. 19C). FIG. 16 shows the trench 109 as having oblique sidewalls that give the trench 109 a tapered profile (e.g., the trench 109 is shown wider near the top than near the bottom), but in other embodiments the trench 109 may have substantially vertical sidewalls, curved sidewalls, or irregular sidewalls.

In some embodiments, the etching process may include one or more etching steps, which may include anisotropic etching steps. The etching process may comprise, for example, a plasma etching process using, for example, a Capacitive Coupling Plasma (CCP), an Inductive Coupling Plasma (ICP), or another type of plasma-generating process. In some embodiments the etching process uses one or more process gases such as Cl₂, HBr, CF₄, CH₂F₂, CHF₃, CH₃F, the like, or combinations thereof. Other process gases are possible. The etching process may include a pressure in the range of about 3 mTorr to about 100 mTorr, though other pressures are possible. The etching process may include a temperature in the range of about −50° C. to about 140 20 C., though other temperatures are possible. The etching process may include an RF power in the range between of 50 Watts to about 2500 Watts, though another RF power is possible. A bias voltage in the range between about 30 volts and about 1000 volts may also be applied, though other voltages are possible. Other etching processes or etching process parameters than these may be used in other embodiments.

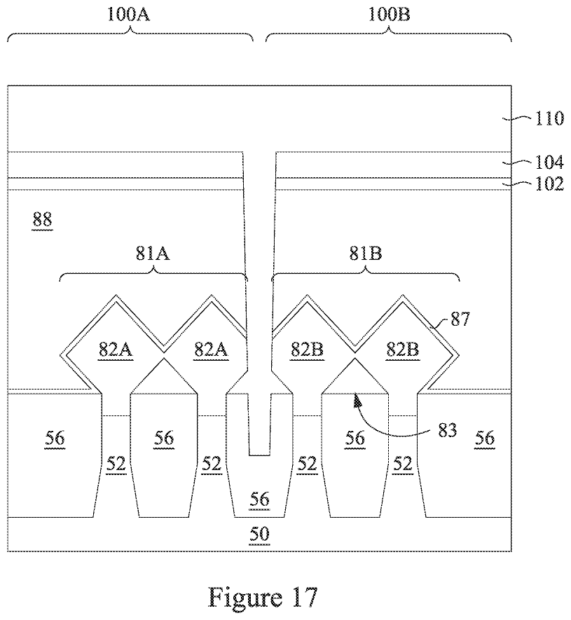

In FIG. 17, an isolation material 110 is deposited over the structure and within the trench 109, in accordance with some embodiments. The isolation material 110 may include a single layer of material or multiple layers of materials, and may partially or completely fill the trench 109. In some embodiments, the isolation material 110 physically contacts a surface of the epitaxial region 82A and a surface of the epitaxial region 82B, and the isolation material 110 may extend partially or completely between these surfaces. The isolation material 110 may comprise one or more dielectric materials, such as silicon oxide, silicon nitride, silicon oxynitride, silicon oxycarbide, silicon carbonitride, silicon oxycarbonitride, the like, or a combination thereof. In some embodiments, the isolation material 110 comprises one or more materials similar to those described previously for the insulation material 54 (see FIG. 4), the mask layer 64 (see FIG. 7), the first ILD 88, and/or the hard mask layer 104. In some embodiments, the isolation material 110 comprises a low-k material. The isolation material 110 may be formed using one or more suitable techniques, such as ALD, PECVD, CVD, spin-on coating, or the like. Other materials or deposition techniques are possible. In other embodiments, the hard mask layer 104 and/or the pad layer 102 are removed prior to depositing the isolation material 110. The hard mask layer 104 and/or the pad layer 102 may be removed, for example, using etching, a planarization process, or the like. In some cases, the isolation material 110 within the trench 109 may have a seam (not shown in the figures) or may enclose an air gap (not shown in the figures). In some embodiments, the isolation material 110 also partially or completely fills the air gap 83 exposed by the trench 109, as shown in FIG. 17.

In FIGS. 18A, 18B, and 18C, a planarization process is performed to remove excess isolation material 110 and form isolation regions 110 (see FIG. 18C), in accordance with some embodiments. The planarization process may comprise, for example, a CMP process, a grinding process, an etching process, or the like. In some embodiments, the planarization process may remove the hard mask layer 104 and the pad layer 102. The planarization process may thin the first ILD 88, in some embodiments. After performing the planarization process, top surfaces of the first ILD 88 and the isolation regions 110 may be level. In some embodiments, the isolation regions 110 may have a height H1 that is in the range of about 20 nm to about 80 nm, which may correspond to the depth D4 of the trench 109 (see FIG. 16) below a top surface of the first ILD 88. The isolation regions 110 may have a width similar to the width W1 of the trench 109 (see FIG. 16). Other heights or widths are possible.

In this manner, a single merged epitaxial structure 81 may be separated into two or more isolated epitaxial structures (e.g., epitaxial structures 81A-B) by an isolation region 110. In some cases, by forming an isolation region 110 that separates merged epitaxial regions 82A-B as described herein, the separation distance D1 (see FIG. 10C) between the adjacent fins 52 can be reduced while keeping the epitaxial regions 82A-B electrically isolated. In this manner, the density of devices of a die or package may be increased, which can reduce the overall area of the die or package. In other embodiments, the adjacent epitaxial regions 82A-B may not be merged, such as shown previously in FIG. 11A. In such embodiments, the formation of an isolation region 110 between the adjacent epitaxial regions 82A-B may allow the adjacent fins 52 to be formed closer together without risk of the epitaxial regions 82A-B being shorted by merging together.

FIGS. 19A through 19H illustrate various isolation regions 110 in accordance with other embodiments. The isolation regions 110 in these figures may be similar to the isolation region 110 described for FIGS. 18A-18C, and may be formed using similar techniques. Other differences between the structures shown in FIGS. 19A-19H and the structure shown in FIGS. 18A-18C, if any, are described in the text accompanying the figure. FIG. 19A shows an embodiment in which the isolation region 110 does not extend significantly into an STI region 56. This embodiment may be formed, for example, by stopping the etching process that forms the trench 109 after the trench 109 is extended completely through the merged epitaxial structure 81 but before the etching process significantly etches the underlying STI region 56. In some embodiments, the etching process that forms the trench 109 may include a selective etch that stops on the material of the STI region 56.

FIG. 19B shows an embodiment in which an isolation region 110 extends completely through the STI region 56 but does not extend significantly into the substrate 50. This embodiment may be formed, for example, by stopping the etching process that forms the trench 109 after the trench 109 is extended completely through the STI region 56 but before the etching process significantly etches the underlying substrate 50. In some embodiments, the etching process that forms the trench 109 may include a selective etch that stops on the material of the substrate 50. FIG. 19C shows an embodiment in which the isolation region 110 extends completely through the STI region 56 and extends into the substrate 50. This embodiment may be formed, for example, by stopping the etching process that forms the trench 109 after the trench 109 extends below a top surface of the substrate 50. In some embodiments, the isolation region 110 may extend below a top surface of the substrate 50 a distance D5 that is in the range of about 2 nm to about 30 nm. Other distances are possible.

FIG. 19D shows an embodiment in which an isolation region 110 isolates previously merged epitaxial regions 82A and 82B, which may be similar to the configuration of epitaxial regions 82A and 82B shown previously in FIG. 11B. After forming the isolation region 110, the epitaxial regions 82A of device region 100A are separated and the epitaxial regions 82B of device region 100B are separated. In this manner, an isolation region 110 may allow for the formation of device regions 100 having separated epitaxial regions 82 even if the adjacent epitaxial regions 82 of two device regions 100 are formed as merged.

FIG. 19E shows an embodiment in which an isolation region 110 isolates previously merged epitaxial regions 82A-B formed in different types of regions 50. For example, FIG. 19E shows a p-type device region 100P-A of a p-type region 50P adjacent to an n-type device region 100N-A of an n-type region 50B. The isolation region 110 shown in FIG. 19E isolates a p-type epitaxial structure 81A of the p-type device region 100P-A from an n-type epitaxial structure 81B of the n-type device region 100N-A. In some embodiments, the adjacent epitaxial regions 82A and 82B may have been merged prior to formation of the isolation region 110. In other embodiments, the adjacent epitaxial regions 82A and 82B may have been separated prior to formation of the isolation region 110. In this manner, an isolation region 110 may allow for devices of different types to be formed closer together. The epitaxial regions 82A-B may have other shapes, sizes, or configurations in other embodiments.

In some embodiments, an isolation region 110 may be formed to separate epitaxial regions 82 of the same device region 100. For example, FIG. 19F shows an embodiment in which an isolation region 110 separates previously merged epitaxial regions 82 of the same device region 100A. The isolation region 110 may separate a merged epitaxial structure (not shown) in a single device region 100A into two epitaxial structures 81A and 81B, in some embodiments. An isolation region 110 may separate a merged epitaxial structure in a single device region 100A into one or more individual epitaxial regions 82, in other embodiments. In this manner, adjacent fins 52 of a single device region 100A may be formed closer together, in some cases.

FIG. 19G shows an embodiment in which portions of the air gap 83 under the merging region 85 (see FIG. 14) remain after forming the isolation region 110. For example, portions of the air gap 83 may remain due to the isolation material 110 (see FIG. 17) incompletely filling an air gap 83 exposed by the trench 109 (see FIG. 16). A remaining portion of the air gap 83 may be present on one or both sides of the isolation region 110, and may extend under the isolation region 110 in some cases. By forming the isolation region 110 such that portions of the air gap 83 remain, parasitic capacitances associated with the adjacent epitaxial regions 82A and 82B may be reduced, in some cases.

FIG. 19H shows an embodiment in which an isolation region 110 is formed extending partially into the trench 109 (see FIG. 16) such that an isolation air gap 183 is formed underneath the isolation region 110. For example, the isolation region 110 may be formed extending below a top surface of the first ILD 88 a distance D6 that is in the range of about 2 nm to about 30 nm, in some embodiments. In some embodiments, the depth D6 of the isolation region 110 may be between about 5% and about 95% of the depth D4 of the trench 109 (see FIG. 16). Other distances are possible. The volume or height of an isolation air gap 183 may be controlled by controlling the depth D6 of the isolation region 110 and/or the depth D4 of the trench 109, in some embodiments. In some cases, the depth D6 of the isolation region 110 may such that the isolation region 110 physically contacts a surface of an epitaxial source/drain region 82. In some embodiments, an isolation air gap 183 may extend below a top surface of an STI region 56 or below a top surface of the substrate 50. The isolation air gap 183 may include a previously formed air gap 83, in some cases. The volume of an isolation air gap 183 may be larger, smaller, or about the same as an air gap 83. In some cases, the formation of an isolation air gap 183 may reduce parasitic capacitances associated with the adjacent epitaxial regions 82A and 82B.

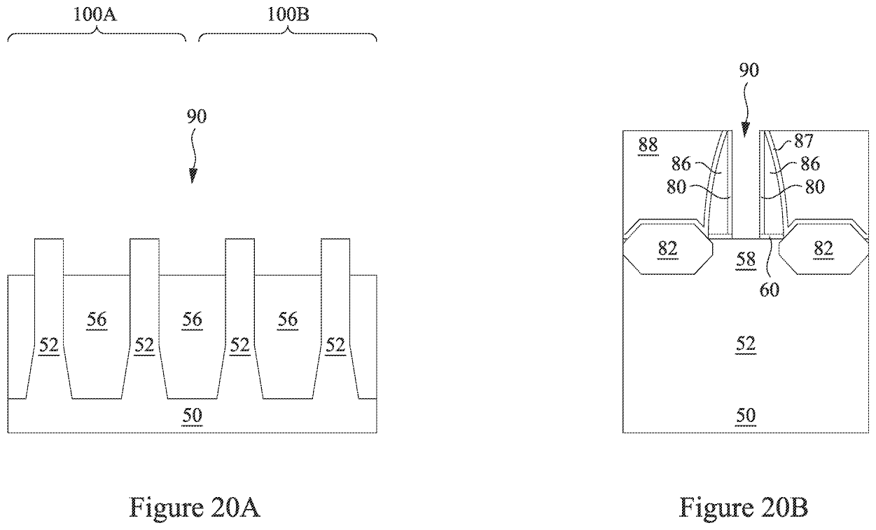

FIGS. 20A through 23C illustrate various additional steps in the manufacturing of embodiment devices. FIGS. 20A-23C show intermediate steps proceeding from the structure shown in FIGS. 18A-18C, but the steps described for FIGS. 20A-23C may also be applicable to other embodiments described herein.

In FIGS. 20A and 20B, the dummy gates 72 and the masks 74 (if present) are removed in one or more etching steps, so that recesses 90 are formed. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process. For example, the etching process may include a dry etch process using reaction gas(es) that selectively etch the dummy gates 72 with little or no etching of the first ILD 88 or the gate spacers 86. Each recess 90 exposes and/or overlies a channel region 58 of a respective fin 52. Each channel region 58 is disposed between neighboring pairs of the epitaxial source/drain regions 82. During the removal, the dummy dielectric layer 60 may be used as an etch stop layer when the dummy gates 72 are etched. The dummy dielectric layer 60 may then be optionally removed after the removal of the dummy gates 72.

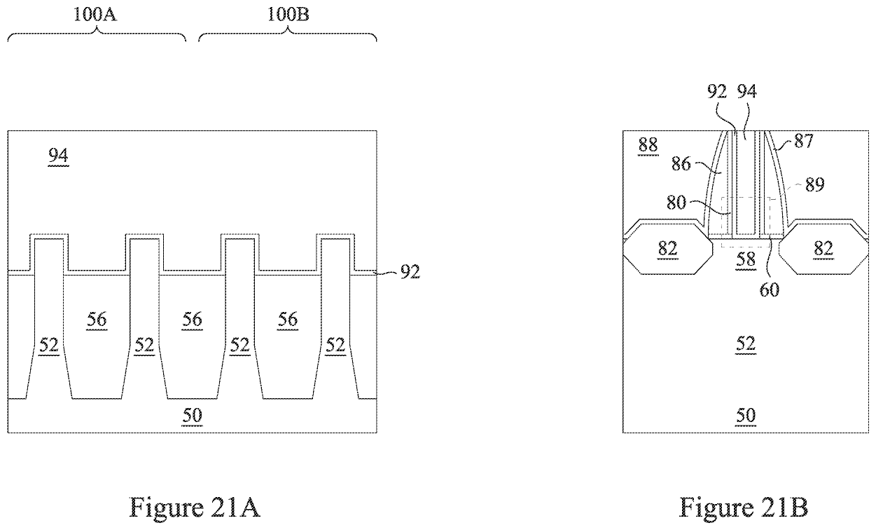

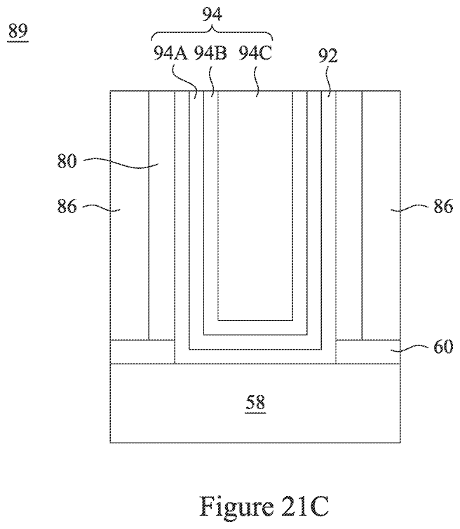

In FIGS. 21A and 21B, gate dielectric layers 92 and gate electrodes 94 are formed for replacement gates. FIG. 21C illustrates a detailed view of region 89 of FIG. 21B. Gate dielectric layers 92 one or more layers deposited in the recesses 90, such as on the top surfaces and the sidewalls of the fins 52 and on sidewalls of the gate seal spacers 80/gate spacers 86. The gate dielectric layers 92 may also be formed on the top surface of the first ILD 88. In some embodiments, the gate dielectric layers 92 comprise one or more dielectric layers, such as one or more layers of silicon oxide, silicon nitride, metal oxide, metal silicate, or the like. For example, in some embodiments, the gate dielectric layers 92 include an interfacial layer of silicon oxide formed by thermal or chemical oxidation and an overlying high-k dielectric material, such as a metal oxide or a silicate of hafnium, aluminum, zirconium, lanthanum, manganese, barium, titanium, lead, the like, or combinations thereof. The gate dielectric layers 92 may include a dielectric layer having a k-value greater than about 7.0. The formation methods of the gate dielectric layers 92 may include Molecular-Beam Deposition (MBD), ALD, PECVD, or the like. In embodiments where portions of the dummy dielectric layer 60 remains in the recesses 90, the gate dielectric layers 92 include a material of the dummy dielectric layer 60 (e.g., silicon oxide).

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, the like, combinations thereof, or multi-layers thereof. For example, although a single layer gate electrode 94 is illustrated in FIG. 21B, the gate electrode 94 may comprise any number of liner layers 94A, any number of work-function tuning layers 94B, and a fill material 94C, as illustrated by FIG. 21C. After the filling of the recesses 90, a planarization process, such as a CMP, may be performed to remove the excess portions of the gate dielectric layers 92 and the material of the gate electrodes 94, which excess portions are over the top surface of the ILD 88. The remaining portions of material of the gate electrodes 94 and the gate dielectric layers 92 thus form replacement gates of the resulting FinFETs. The gate electrodes 94 and the gate dielectric layers 92 may be collectively referred to as a “replacement gate,” a “gate structure,” or a “gate stack.” The gate and the gate stacks may extend along sidewalls of a channel region 58 of the fins 52.

The formation of the gate dielectric layers 92 in the n-type region 50N and the p-type region 50P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

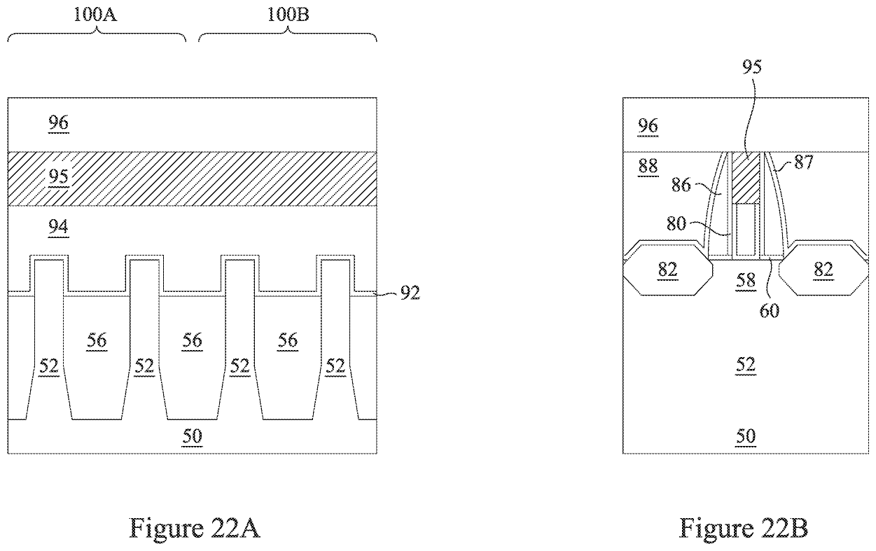

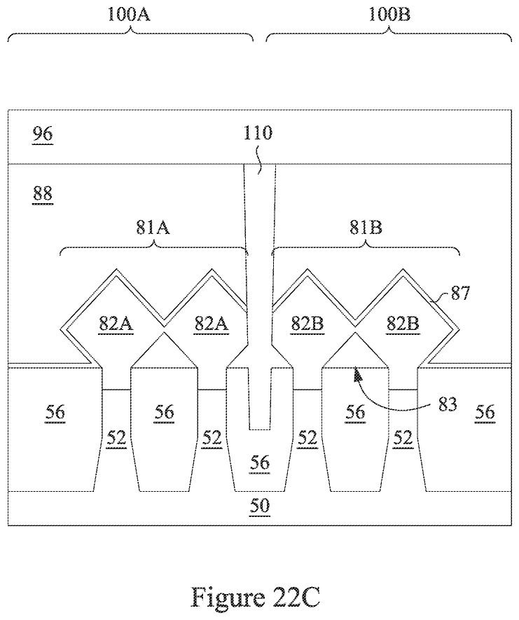

In FIGS. 22A, 22B, and 22C, a gate mask 95 is formed over the gate stack (including a gate dielectric layer 92 and a corresponding gate electrode 94), and the gate mask may be disposed between opposing portions of the gate spacers 86. In some embodiments, forming the gate mask 95 includes recessing the gate stack so that a recess is formed directly over the gate stack and between opposing portions of gate spacers 86. A gate mask 95 comprising one or more layers of dielectric material, such as silicon nitride, silicon oxynitride, or the like, is filled in the recess, followed by a planarization process to remove excess portions of the dielectric material extending over the first ILD 88 and the isolation region 110. The gate mask 95 is optional and may be omitted in some embodiments. In such embodiments, the gate stack may remain level with top surfaces of the first ILD 88.

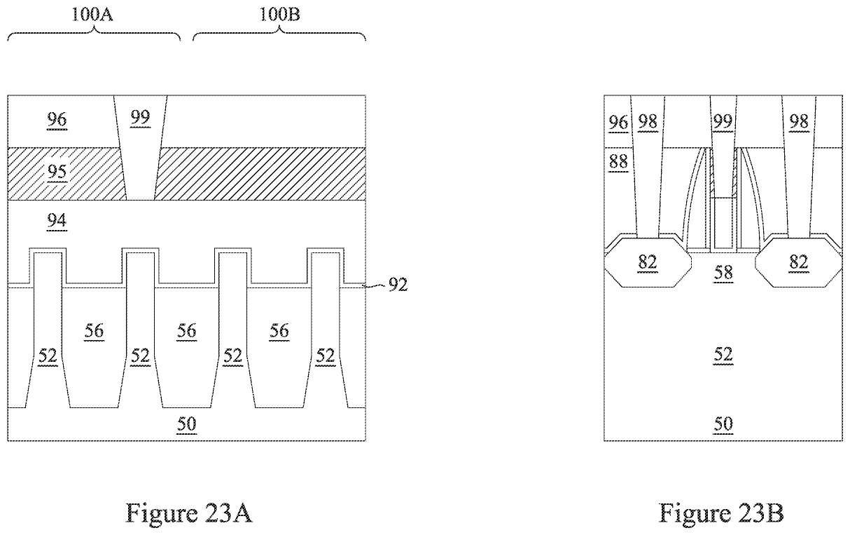

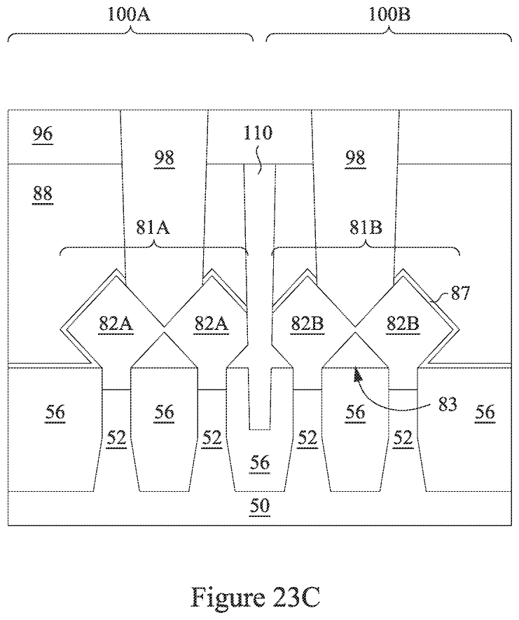

As also illustrated in FIGS. 22A-22C, a second ILD 96 is deposited over the first ILD 88 and the isolation region 110. In some embodiments, the second ILD 96 is a flowable film formed by a flowable CVD method. In some embodiments, the second ILD 96 is formed of a dielectric material such as PSG, BSG, BPSG, USG, or the like, and may be deposited by any suitable method, such as CVD and PECVD. The subsequently formed gate contacts 99 (FIGS. 23A-23B) penetrate through the second ILD 96 and the gate mask 95 (if present) to contact the top surface of the recessed gate electrode 94.

In FIGS. 23A, 23B, and 23C, gate contacts 99 and source/drain contacts 98 are formed through the first ILD 88 and the second ILD 96, in accordance with some embodiments. Openings for the source/drain contacts 98 are formed through the first ILD 88 and the second ILD 96, and openings for the gate contact 99 are formed through the second ILD 96 and the gate mask 95 (if present). The openings may be formed using acceptable photolithography and etching techniques. A liner (not shown), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, the like, or a combination thereof. A planarization process, such as a CMP, may be performed to remove excess material from a surface of the second ILD 96. The remaining liner and conductive material form the source/drain contacts 98 and gate contacts 99 in the openings. An anneal process may be performed to form a silicide (not shown) at the interface between the epitaxial source/drain regions 82 and the source/drain contacts 98. The source/drain contacts 98 are physically and electrically coupled to the epitaxial source/drain regions 82, and the gate contacts 99 are physically and electrically coupled to the gate electrodes 94. The source/drain contacts 98 and gate contacts 99 may be formed in different processes, or may be formed in the same process. Although shown as being formed in the same cross-sections, it should be appreciated that each of the source/drain contacts 98 and gate contacts 99 may be formed in different cross-sections, which may avoid shorting of the contacts.

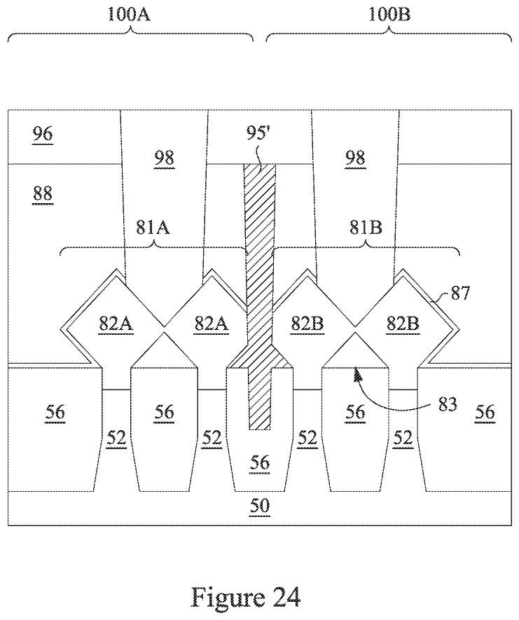

In some embodiments, the isolation regions between merged epitaxial regions 82 may be formed at a different step during the manufacturing of devices than described above. As an example, in some embodiments, the isolation regions may be formed after formation of the gate stack. In some embodiments, the formation of the isolation regions may be combined with other process steps. As an example, FIG. 24 illustrates an embodiment in which the trench 109 (see FIG. 16) is formed after formation of the gate stack, and the material of the gate mask 95 is also deposited into the trench 109 to form an isolation region 95′ simultaneously with the gate mask 95. This is an example, and the material of other features may be simultaneously deposited into the trench 109 to form an isolation region, such as the material of the second ILD 96 or the material of an etch stop layer (not shown) formed on the first ILD 88. The formation of the isolation regions may be performed at different steps or combined with other steps than these examples.

The disclosed FinFET embodiments could also be applied to nanostructure devices such as nanostructure (e.g., nanosheet, nanowire, gate-all-around, or the like) field effect transistors (NSFETs). In an NSFET embodiment, the fins are replaced by nanostructures formed by patterning a stack of alternating layers of channel layers and sacrificial layers. Dummy gate stacks and source/drain regions are formed in a manner similar to the above-described embodiments. After the dummy gate stacks are removed, the sacrificial layers can be partially or fully removed in channel regions. The replacement gate structures are formed in a manner similar to the above-described embodiments, the replacement gate structures may partially or completely fill openings left by removing the sacrificial layers, and the replacement gate structures may partially or completely surround the channel layers in the channel regions of the NSFET devices. ILDs and contacts to the replacement gate structures and the source/drain regions may be formed in a manner similar to the above-described embodiments. A nanostructure device can be formed as disclosed in U.S. Pat. No. 9,647,071, which is incorporated herein by reference in its entirety.

The embodiments described herein may have some advantages. In some cases, the use of an isolation region to separate and isolate merged epitaxial regions can allow fins to be formed closer together (e.g., have a smaller pitch), which can increase device density. Additionally, the use of an isolation region may allow for larger epitaxial regions to be formed, as the isolation region can prevent adjacent epitaxial regions from being shorted together by merging. In some cases, epitaxial regions with larger volumes or dimensions can reduce resistance and improve device operation. In some cases, an isolation region may comprise an air gap or a material having a relatively low k-value, which can reduce parasitic capacitance and improve device operation.

In accordance with some embodiments of the present disclosure, a method includes forming a first fin and a second fin protruding from a substrate; forming an isolation layer surrounding the first fin and the second fin; epitaxially growing a first epitaxial region on the first fin and a second epitaxial region on the second fin, wherein the first epitaxial region and the second epitaxial region are merged together; performing an etching process on the first epitaxial region and the second epitaxial region, wherein the etching process separates the first epitaxial region from the second epitaxial region; depositing a dielectric material between the first epitaxial region and the second epitaxial region; and forming a first gate stack extending over the first fin. In an embodiment, the first fin and the second fin are separated by a distance in the range of 26 nm to 190 nm. In an embodiment, the dielectric material includes silicon carbonitride. In an embodiment, the first epitaxial region is a source/drain region of a first Fin Field-Effect Transistor (FinFET) and the second epitaxial region is a source/drain region of a second FinFET. In an embodiment, a bottom surface of the dielectric material is closer to the substrate than a top surface of the isolation layer. In an embodiment, a bottom surface of the dielectric material extends below a top surface of the substrate. In an embodiment, the dielectric material physically contacts a sidewall of the first epitaxial region and a sidewall of the second epitaxial region. In an embodiment, after performing the etching process, the first epitaxial region is separated from the second epitaxial region by a distance in the range of 8 nm to 30 nm.

In accordance with some embodiments of the present disclosure, a method includes forming fins extending over a substrate; forming epitaxial source/drain regions on the fins, wherein the epitaxial source/drain regions are merged together to form a merged epitaxial structure; forming a dielectric layer over the merged epitaxial structure; etching a first trench extending through the dielectric layer and through the merged epitaxial structure; depositing an insulating material into the first trench; and forming a gate structure extending over the plurality of fins. In an embodiment, the fins have a first pitch in the range of 36 nm to 200 nm. In an embodiment, depositing an insulating material into the first trench forms an air gap in the first trench under the insulating material. In an embodiment, the method includes forming a second trench extending through the dielectric layer and through the merged epitaxial structure and depositing the insulating material into the second trench. In an embodiment, the merged epitaxial structure includes n-type epitaxial source/drain regions and p-type epitaxial source/drain regions. In an embodiment, a bottom surface of the first trench is farther from the substrate than a bottom surface of the merged epitaxial structure. In an embodiment, the insulating material extends underneath the merged epitaxial structure.

In accordance with some embodiments of the present disclosure, a semiconductor device includes a substrate; a first transistor device on the substrate, the first transistor device including: first fins extending on the substrate, wherein adjacent first fins are respectively separated by a first distance; first epitaxial source/drain regions on the first fins, wherein adjacent first epitaxial source/drain regions are respectively merged together; and a first gate structure extending over the first fins; a second transistor device on the substrate adjacent the first transistor device, the second transistor device including: second fins extending on the substrate, wherein adjacent second fins are respectively separated by the first distance, wherein a first fin is separated from a second fin by the first distance; second epitaxial source/drain regions on the second fins, wherein adjacent second epitaxial source/drain regions are respectively merged together; and a second gate structure extending over the second fins; and an isolation region between a first epitaxial source/drain region and a second epitaxial source/drain region, wherein the isolation region physically contacts the first epitaxial source/drain region and the second epitaxial source/drain region, wherein the isolation region includes a first insulating material. In an embodiment, the semiconductor device includes a second insulating material over the first epitaxial source/drain region and over the second epitaxial source/drain region, wherein the second insulating material is different from the first insulating material. In an embodiment, top surfaces of the first insulating material and the second insulating material are level. In an embodiment, the semiconductor device includes a mask material on the first gate structure, wherein the first insulating material and the mask material are the same material. In an embodiment, the first transistor device includes a separate fin that is adjacent the first fins and a separate epitaxial source/drain region on the separate fin that is separated from the first epitaxial source/drain regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first fin and a second fin protruding from a substrate;
forming an isolation layer surrounding the first fin and the second fin;
epitaxially growing a first epitaxial region on the first fin and a second epitaxial region on the second fin, wherein the first epitaxial region and the second epitaxial region are merged together;
performing an etching process on the first epitaxial region and the second epitaxial region, wherein the etching process separates the first epitaxial region from the second epitaxial region;
depositing a dielectric material between the first epitaxial region and the second epitaxial region; and
forming a first gate stack extending over the first fin.

2. The method of claim 1, wherein the first fin and the second fin are separated by a distance in the range of 26 nm to 190 nm.

3. The method of claim 1, wherein the dielectric material comprises silicon carbonitride.

4. The method of claim 1, wherein the first epitaxial region is a source/drain region of a first Fin Field-Effect Transistor (FinFET) and the second epitaxial region is a source/drain region of a second FinFET.

5. The method of claim 1, wherein a bottom surface of the dielectric material is closer to the substrate than a top surface of the isolation layer.

6. The method of claim 1, wherein a bottom surface of the dielectric material extends below a top surface of the substrate.

7. The method of claim 1, wherein the dielectric material physically contacts a sidewall of the first epitaxial region and a sidewall of the second epitaxial region.

8. The method of claim 1, wherein after performing the etching process, the first epitaxial region is separated from the second epitaxial region by a distance in the range of 8 nm to 30 nm.

9. A method comprising:
forming a plurality of fins extending over a substrate;
forming a plurality of epitaxial source/drain regions on the plurality of fins, wherein the plurality of epitaxial source/drain regions are merged together to form a merged epitaxial structure;
forming a dielectric layer over the merged epitaxial structure;
etching a first trench extending through the dielectric layer and through the merged epitaxial structure;
depositing an insulating material into the first trench; and
forming a gate structure extending over the plurality of fins.

10. The method of claim 9, wherein the fins of the plurality of fins have a first pitch in the range of 36 nm to 200 nm.

11. The method of claim 9, wherein depositing an insulating material into the first trench forms an air gap in the first trench under the insulating material.

12. The method of claim 9 further comprising:
forming a second trench extending through the dielectric layer and through the merged epitaxial structure; and
depositing the insulating material into the second trench.

13. The method of claim 9, wherein the merged epitaxial structure comprises n-type epitaxial source/drain regions and p-type epitaxial source/drain regions.

14. The method of claim 9, wherein a bottom surface of the first trench is farther from the substrate than a bottom surface of the merged epitaxial structure.

15. The method of claim 9, wherein the insulating material extends underneath the merged epitaxial structure.

16. A semiconductor device, comprising:
a substrate;
a first transistor device on the substrate, the first transistor device comprising:
a first plurality of fins extending on the substrate, wherein adjacent fins of the first plurality of fins are respectively separated by a first distance;
a first plurality of epitaxial source/drain regions on the first plurality of fins, wherein adjacent epitaxial source/drain regions of the first plurality of epitaxial source/drain regions are respectively merged together; and
a first gate structure extending over the first plurality of fins;
a second transistor device on the substrate adjacent the first transistor device, the second transistor device comprising:
a second plurality of fins extending on the substrate, wherein adjacent fins of the second plurality of fins are respectively separated by the first distance, wherein a first fin of the first plurality of fins is separated from a second fin of the second plurality of fins by the first distance;
a second plurality of epitaxial source/drain regions on the second plurality of fins, wherein adjacent epitaxial source/drain regions of the second plurality of epitaxial source/drain regions are respectively merged together; and
a second gate structure extending over the second plurality of fins; and
an isolation region between a first epitaxial source/drain region of the first plurality of epitaxial source/drain regions and a second epitaxial source/drain region of the second plurality of epitaxial source/drain regions, wherein the isolation region physically contacts the first epitaxial source/drain region and the second epitaxial source/drain region, wherein the isolation region comprises a first insulating material.

17. The semiconductor device of claim 16 further comprising a second insulating material over the first epitaxial source/drain region and over the second epitaxial source/drain region, wherein the second insulating material is different from the first insulating material.

18. The semiconductor device of claim 17, wherein top surfaces of the first insulating material and the second insulating material are level.

19. The semiconductor device of claim 16 further comprising a mask material on the first gate structure, wherein the first insulating material and the mask material are the same material.

20. The semiconductor device of claim 16, wherein the first transistor device further comprises a separate fin that is adjacent the first plurality of fins and a separate epitaxial source/drain region on the separate fin that is separated from the first plurality of epitaxial source/drain regions.
